(19) United States
(12) Patent Application Publication
(10) Pub. No.: US 2019/0254164 A1
(43) Pub. Date: Aug. 15, 2019

(54) CIRCUIT BOARD, METHOD OF MANUFACTURING CIRCUIT BOARD, AND ELECTRONIC DEVICE

(71) Applicant: FUJITSU LIMITED, Kawasaki-shi (JP)

(72) Inventors: Toshiki Iwai, Atsugi (JP); Taiji Sakai, Yokohama (JP)

(73) Assignee: FUJITSU LIMITED, Kawasaki-shi (JP)

(21) Appl. No.: 16/252,013

(22) Filed: Jan. 18, 2019

(30) Foreign Application Priority Data
Feb. 9, 2018 (JP) 2018-021857

(51) Int. Cl. H05K 1/11; H05K 1/05; H05K 1/02; H05K 3/44; H05K 3/32; H05K 3/46

(52) U.S. Cl. CPC H05K 1/115; H05K 1/056; H05K 3/46; H05K 3/445; H05K 3/32; H05K 1/0298

(57) ABSTRACT

A circuit board includes a first substrate of a fragile material, a first through-hole formed in the first substrate for allowing a screw for fixing the first substrate to a supporting body to be inserted through the first through-hole, a first step formed at an outer edge of a first region surrounding the first through-hole in the first substrate, and a second step formed along a direction from the first through-hole to the first step in the first region of the first substrate.

### CROSS-REFERENCE TO RELATED APPLICATION

This application is based upon and claims the benefit of priority of the prior Japanese Patent Application No. 2018-21857, filed on Feb. 9, 2018, the entire contents of which are incorporated herein by reference.

### FIELD

The embodiments discussed herein are related to a circuit board, a method of manufacturing a circuit board, and an electronic device.

### BACKGROUND

As one of methods of fixing a circuit board such as a printed board to a supporting body such as a housing, there is known a method using a screw. For example, there is known a method including: forming a hole for substrate fixing, into which a screw is inserted, in a printed board; forming a screw fixing section, to which the screw is fixed, in a housing; and inserting the screw into the hole of the printed board and tightening the screw to the screw fixing section of the housing to directly fix the printed board to the housing with the screw.

Incidentally, from a viewpoint of a reduction in size, high integration, high functionality, and the like of an electronic device and an electronic apparatus using a circuit board, glass is sometimes used as an insulating base material of the circuit board.

In the circuit board in which glass, which is a fragile material, is used as the insulating base material, if the method of directly fixing a circuit board to a supporting body such as a housing with a screw is used, it is likely that a crack and a break are caused in the glass by stress generated near a through-hole into which the screw is inserted during the tightening. If a crack and a break of the glass extend from the through-hole to a relatively wide range around the through-hole, for example, it is likely that the crack and the break reach a wire formed on the glass, cause a resistance increase and an open failure of the wire, and deteriorate performance and reliability of the circuit board.

Such deterioration in performance and reliability of a circuit board due to a crack and a break by stress during the tightening of a screw could occur not only in glass but also in circuit boards in which various fragile materials are used as insulating base materials.

The following is a reference document.

### [Document 1] Japanese Laid-open Patent Publication No. 2008-187012.

### SUMMARY

According to an aspect of the embodiments, a circuit board includes a first substrate of a fragile material, a first through-hole formed in the first substrate for allowing a screw for fixing the first substrate to a supporting body to be inserted through the first through-hole, a first step formed at an outer edge of a first region surrounding the first through-hole in the first substrate, and a second step formed along a direction from the first through-hole to the first step in the first region of the first substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are explanatory diagrams of an example of a method of fixing a circuit board;

FIGS. 2A and 2B are diagrams illustrating an example of a circuit board according to a first embodiment;

FIGS. 3A and 3B are diagrams illustrating an example of an electronic device according to the first embodiment;

FIGS. 4A to 4C are diagrams illustrating modifications of a step of the circuit board according to the first embodiment;

FIGS. 5A and 5B are diagrams illustrating a first configuration example of the circuit board according to the first embodiment;

FIGS. 6A to 6C are diagrams illustrating a second configuration example of the circuit board according to the first embodiment;

FIGS. 7A to 7C are diagrams illustrating a third configuration example of the circuit board according to the first embodiment;

FIGS. 8A and 8B are diagrams illustrating an example of a circuit board according to a second embodiment;

FIGS. 9A to 9C are diagrams illustrating modifications of a step of the circuit board according to the second embodiment;

FIGS. 10A and 10B are diagrams illustrating an example of a circuit board according to a third embodiment;

FIG. 11 is a diagram illustrating another example of the circuit board according to the third embodiment;

FIGS. 12A to 12D are explanatory diagrams (No. 1) of a stress analysis according to a fourth embodiment;

FIGS. 13A to 13D are explanatory diagrams (No. 2) of the stress analysis according to the fourth embodiment;

FIGS. 14A to 14D are diagrams (No. 1) illustrating a first example of a method of forming a circuit board according to a fifth embodiment;

FIGS. 15A and 15B are diagrams (No. 2) illustrating the first example of the method of forming the circuit board according to the fifth embodiment;

FIGS. 16A to 16D are diagrams (No. 1) illustrating a second example of the method of forming the circuit board according to the fifth embodiment;

FIGS. 17A to 17C are diagrams (No. 2) illustrating the second example of the method of forming the circuit board according to the fifth embodiment;

FIG. 18 is a diagram illustrating an example of an electronic device according to a sixth embodiment; and

FIG. 19 is an explanatory diagram of an electronic apparatus according to a seventh embodiment.

### DESCRIPTION OF EMBODIMENTS

First, an example of a method of fixing a circuit board is explained.

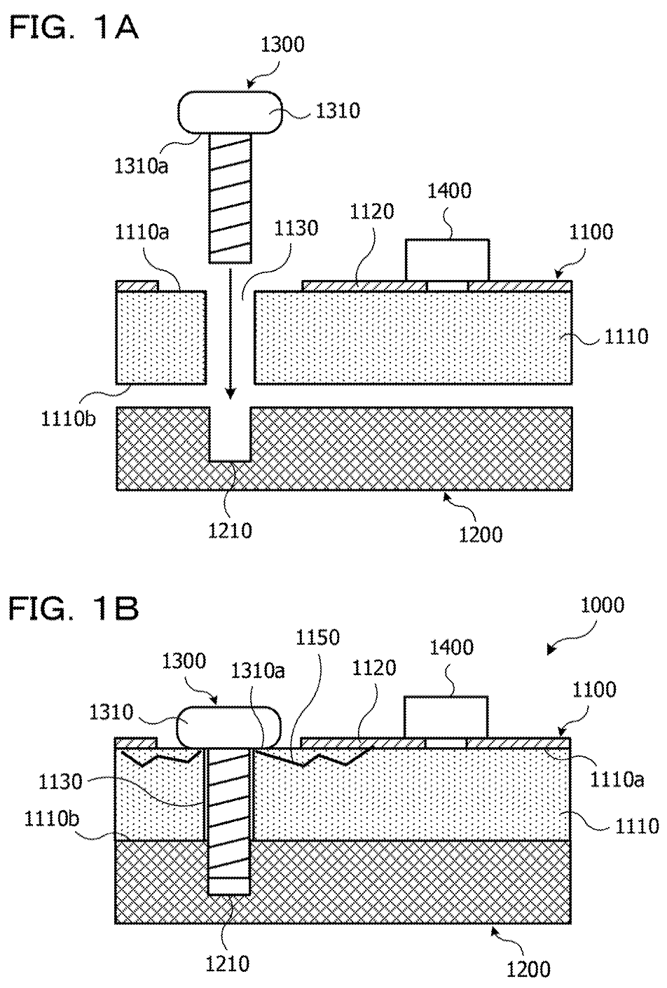

FIGS. 1A and 1B are explanatory diagrams of the example of the method of fixing the circuit board. In FIG. 1A, a main part sectional view of an example of a state before fixing is schematically illustrated. In FIG. 1B, a maim part sectional view of an example of a state after fixing is schematically illustrated.

An example is explained in which a circuit board 1100 is fixed to a supporting body 1200 by a screw 1300.

In the circuit board 1100, a glass substrate 1110 of a fragile material is used as an insulating base material of the circuit board 1100. The glass substrate 1110 has relatively high flatness and a relatively small thermal expansion coefficient difference from a semiconductor chip or the like mounted on the glass substrate 1110. Therefore, deformation such as warp and waviness is reduced. It is possible to form a high-density conductor pattern. Therefore, according to high density of a conductor pattern, a reduction in the size of a bump such as solder, and the like, it is possible to achieve a reduction in the size and high density of the semiconductor chip or the like mounted on the circuit board 1100 and a reduction in the size, high integration, and high functionality of an electronic device and an electronic apparatus including the circuit board 1100. From such a viewpoint, it is effective to use the glass substrate 1110 as the insulating base material of the circuit board 1100.

A wire 1120 having a predetermined pattern shape is formed on one surface (an upper surface) 1110a of the glass substrate 1110. An electronic component 1400 such as a semiconductor chip is mounted to be electrically and mechanically connected to the wire 1120. In the glass substrate 1110, a wire having a predetermined pattern shape may be formed on the other surface (a lower surface) 1110b as well. In the glass substrate 1110, a through-hole 1130 that pierces through between the upper surface 1110a and the lower surface 1110b and through which the screw 1300 for fixing the glass substrate 1110 to the supporting body 1200 is inserted is formed. A screw groove, in which a thread ridge of the screw 1300 is screwed, is not formed on the inner surface of the through-hole 1130. A fixed gap may be set between the inner surface of the through-hole 1130 and the screw 1300 inserted through the through-hole 1130.

The supporting body 1200 is a housing of an electronic device or an electronic apparatus on which the circuit board 1100 mounted with the electronic component 1400 is mounted or a predetermined member, component, or the like in the housing. In the supporting body 1200, various material such as a metal material, a resin material, and a ceramic material are used. In the supporting body 1200, a fixing section 1210, which is a screw hole, to which the screw 1300 is tightened, screwed, and fixed is formed in a position corresponding to the through-hole 1130 formed in the circuit board 1100 (the glass substrate 1110 of the circuit board 1100).

When the circuit board 1100 is fixed to the supporting body 1200, as illustrated in FIG. 1A, the circuit board 1100 and the supporting body 1200 are opposed with the through-hole 1130 and the fixing section 1210 thereof aligned. The screw 1300 is inserted through the through-hole 1130 of the circuit board 1100 and tightened to the fixing section 1210 of the supporting body 1200. According to the tightening of the screw 1300, a surface 1310a on the lower side (a lower surface) of a head 1310 of the screw 1300 is brought into contact with the upper surface 1110a of the glass substrate 1110. The electronic device 1000 illustrated in FIG. 1B in which the circuit board 1100 is directly fixed to the supporting body 1200 by the screw 1300 is obtained.

However, in the method of directly fixing the circuit board 1100 to the supporting body 1200 by the screw 1300, the glass substrate 1110 of the fragile material is used in the circuit board 1100. Therefore, a problem described below is likely to occur.

That is, for example, in the glass substrate 1110, relatively large stress is generated in a region near the through-hole 1130, with which the head 1310 of the screw 1300 is brought into contact when the screw 1300 is tightened. In the glass substrate 1110 of the fragile material, as illustrated in FIG. 1B, damage 1150 such as a crack and a break extending starting from the through-hole 1130 or the vicinity of the through-hole 1130 is likely to be caused by stress generated when the screw 1300 is tightened in this way. For example, when the caused damage 1150 extends to reach the wire 1120 on the glass substrate 1110, a crack and disconnection are likely to occur in the wire 1120 to cause a resistance increase and an open failure. Since the damage 1150 occurs in the glass substrate 1110, strength insufficiency and a fixing failure (a wobble or the like) of the circuit board 1100 are likely to be caused.

In a method of directly fixing the circuit board 1100 to the supporting body 1200 with the screw 1300, performance and reliability of the circuit board 1100 are likely to be deteriorated.

The circuit board 1100 including the glass substrate 1110 as the insulating base material is explained as the example. However, the problems described above in directly fixing the circuit board 1100 with the screw 1300 could also occur in circuit boards including, as insulating base materials, substrates of various fragile materials such as a silicon substrate, a sapphire substrate, and a ceramic substrate.

In view of the points explained above, configurations explained as embodiments below are adopted.

First, a first embodiment is explained.

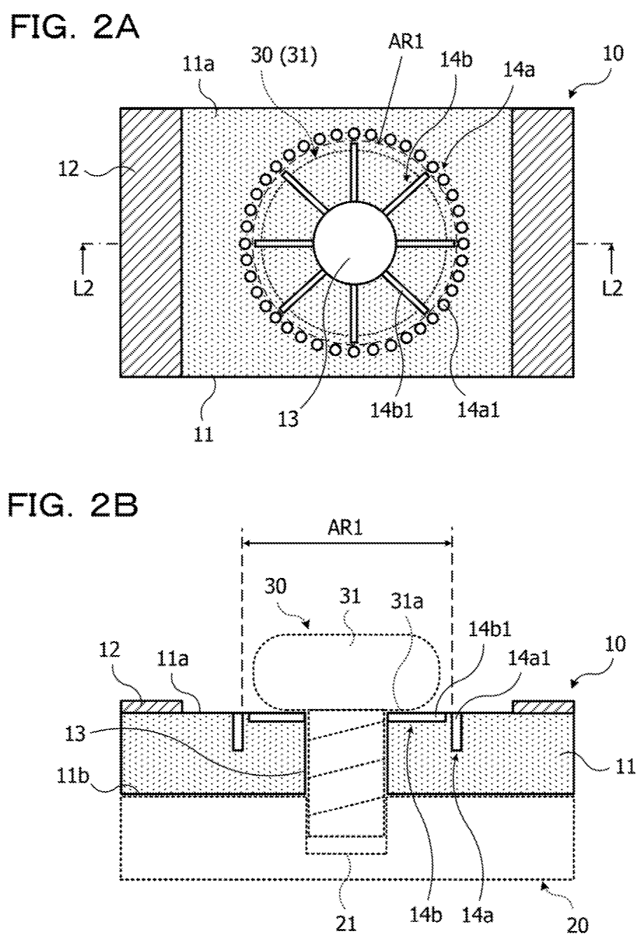

FIGS. 2A and 2B are diagrams illustrating an example of a circuit board according to the first embodiment. In FIG. 2A, a main part plan view of the example of the circuit board is schematically illustrated. In FIG. 2B, a main part sectional view of the example of the circuit board is schematically illustrated. FIG. 2B is a IIB-IIB sectional schematic view of FIG. 2A. In FIGS. 2A and 2B, for convenience, a supporting body that fixes the circuit board and a screw for fixing the circuit board to the supporting body are respectively indicated by dotted lines.

In a circuit board 10 illustrated in FIGS. 2A and 2B, a glass substrate 11 of a fragile material is used as an insulating base material of the circuit board 10. The glass substrate 11 has relatively high flatness and a relatively small thermal expansion coefficient difference from a semiconductor chip or the like. Therefore, deformation such as warp and waviness is reduced. It is possible to form a high-density conductor pattern. Therefore, according to high density of a conductor pattern, a reduction in the size of a bump such as solder, and the like, it is possible to achieve a reduction in the size and high density of the semiconductor chip or the like mounted on the circuit board 10 and a reduction in the size, high integration, and high functionality of an electronic device and an electronic apparatus including the circuit board 10 is used. From such a viewpoint, it is effective to use the glass substrate 11 as the insulating base material of the circuit board 10.

A wire 12 having a predetermined pattern shape is formed on one surface (an upper surface) 11a of the glass substrate 11. In the glass substrate 11, a wire having a predetermined pattern shape may be formed on the other surface (a lower surface) 11b as well. In the glass substrate 11, a through-hole 13 that pierces through between the upper surface 11a and the lower surface 11b and through which a screw 30 for fixing the glass substrate 11 to a supporting body 20 is formed. A screw groove, in which a thread ridge of the screw 30 is screwed, is not formed on the inner surface of the through-hole 13. A fixed gap may be formed between the inner surface of the through-hole 13 and the screw 30 inserted through the through-hole 13.

A step 14a and a step 14b are formed on the upper surface 11a in the glass substrate 11 included in the circuit board 10. The step 14a is formed at the outer edge of a region AR1 surrounding the through-hole 13 in the glass substrate 11. The step 14b is formed on the inside of the region AR1. The region AR1 is a region including a part where a head 31 of the tightened screw 30 comes into contact with the glass substrate 11 when the circuit board 10 including the glass substrate 11 is fixed to the supporting body 20 by the screw 30. In FIGS. 2A and 2B, as an example, the region AR1 surrounding the through-hole 13 in a circumferential shape in a plan view is illustrated. However, the shape of the region AR1 is not limited to this. Various shapes such as a square shape or a hexagonal shape in the plan view may be adopted.

Both of the step 14a and the step 14b include unevenness formed by holes, grooves, and the like formed on the glass substrate 11.

For example, as illustrated in FIGS. 2A and 2B, the step 14a formed at the outer edge of the region AR1 includes a plurality of holes 14a1 arranged along the outer edge of the region AR1 and includes a step formed by a group of the holes 14a1. For example, as illustrated in FIGS. 2A and 2B, the step 14b formed on the inner side of the region AR1 includes a plurality of grooves 14b1 radially extended along a direction from the through-hole 13 to the step 14a at the outer edge of the region AR1 and includes steps formed by a group of the grooves 14b1. In this case, the respective holes 14a1 and the respective grooves 14b1 are equivalent to recesses. Sections among the holes 14a1 and among the grooves 14b1 are equivalent to projections. For example, the recesses are parts where the thickness of the glass substrate 11 is smaller than the thickness of the peripheries of the recesses. The projections are parts where the thickness of the glass substrate 11 is larger than the thickness of the peripheries of the projections.

The step 14a and the step 14b are desirably formed such that the depth of the recesses with respect to the projections is equal to or larger than a microcrack that occurs in the glass substrate 11, for example, depth equal to or larger than 0.5 μm. When the recesses of the step 14a and the step 14b are set to such depth, as explained below, a crack and a break easily occur in the recesses of the step 14a and the step 14b and extension of the crack and the break to the outer side of the region AR1 less easily occurs.

The group of the holes 14a1 of the step 14a may or may not pierce through between the upper surface 11a and the lower surface 11b of the glass substrate 11. The group of the grooves 14b1 of the step 14b may or may not communicate with the through-hole 13 of the glass substrate 11. The group of the grooves 14b1 may or may not communicate with the holes 14a1 of the step 14a.

The circuit board 10 having the configuration explained above is fixed to the supporting body 20 by the screw 30 to form an electronic device.

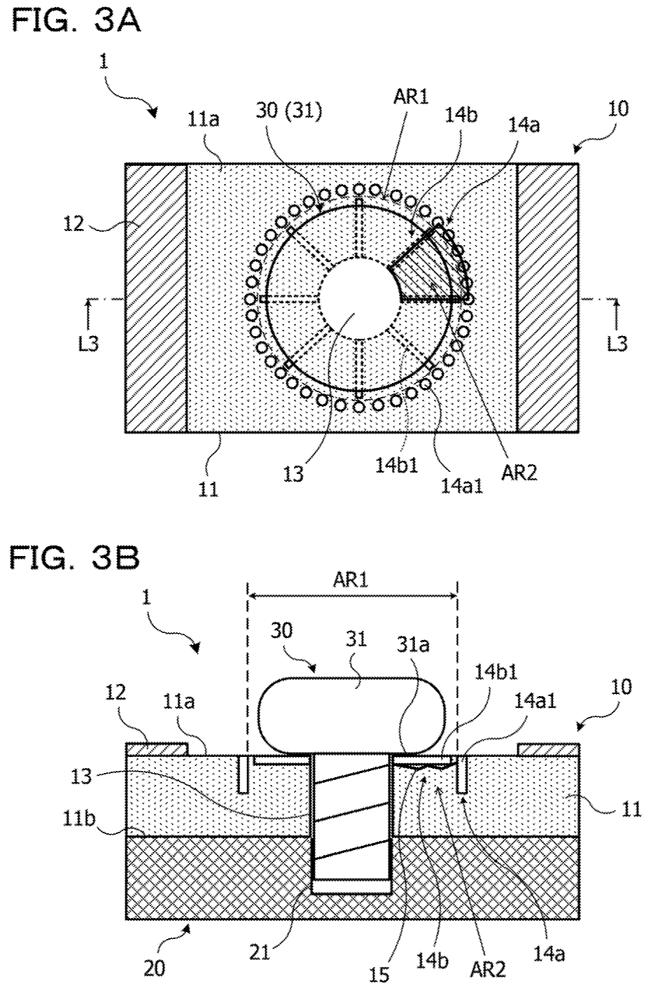

FIGS. 3A and 3B are diagrams illustrating an example of the electronic device according to the first embodiment. In FIG. 3A, a main part plan view of an example of the electronic device is schematically illustrated. In FIG. 3B, a main part sectional view of the example of the electronic device is schematically illustrated. FIG. 3B is a IIIB-IIIB sectional schematic view of FIG. 3A.

The supporting body 20 to which the circuit board 10 is fixed is a housing of an electronic device or an electronic apparatus mounted with the circuit board 10 or is a predetermined member, component, or the like in the housing. In the supporting body 20, various materials such as a metal material, a resin material, and a ceramic material are used. In the supporting body 20, a fixing section 21, which is a screw hole, to which the screw 30 is tightened, screwed, and fixed is formed in a position corresponding to the through-hole 13 formed in the circuit board 10 (the glass substrate 11 of the circuit board 10).

The circuit board 10 and the supporting body 20 are opposed with the through-hole 13 and the fixing section 21 thereof aligned. The screw 30 is inserted through the through-hole 13 of the circuit board 10 and tightened to the fixing section 21 of the supporting body 20. According to the tightening of the screw 30, the head 31 of the screw 30 is brought into contact with the glass substrate 11. The circuit board 10 is directly fixed to the supporting body 20 by the screw 30. Consequently, an electronic device 1 illustrated in FIGS. 3A and 3B is obtained.

When the screw 30 is tightened, a lower surface 31a of the screw 30 comes into contact with the projections (in this example, the parts among the grooves 14b1) of the step 14b formed in the region AR1 of the glass substrate 11. In the glass substrate 11, relatively large stress occurs in a region near the through-hole 13, with which the lower surface 31a of the head 31 is brought into contact, when the screw 30 is tightened. In the glass substrate 11 of the fragile material, for example, as illustrated in FIG. 3B, damage 15 such as a crack or a break extending starting from the through-hole 13 or the vicinity of the through-hole 13 could be caused by such stress generated when the screw 30 is tightened.

The damage 15 easily occurs from the groove 14b1, which is the recess, of the step 14b, for example, the edge of the bottom of the groove 14b1 when the screw 30 comes into contact with the projection of the step 14b in the region AR1 and is easily led to extend toward the outside of the through-hole 13. In the circuit board 10, the step 14a including the group of the holes 14a1 at the outer edge of the region AR1 is formed on the outer side of the step 14b in the region AR1 where such damage 15 could occur. Consequently, when the damage 15 that occurs in the region AR1 extends to the step 14a at the outer edge of the region AR1, the extension is stopped (terminated) in at least one hole 14a1 of the step 14a. Further extension to the outer side than the step 14a is reduced.

In the circuit board 10, since the group of the holes 14a1 is formed along the outer edge of the region AR1, the damage 15 more easily extends in a direction for connecting the holes 14a1 adjacent to one another than in a direction toward the outer side of the group of the holes 14a1. Therefore, in the circuit board 10, for example, as illustrated in FIG. 3A, the damage 15 easily occurs in each region AR2 surrounded by a part (a projection) sandwiched by the group of a pair of grooves 14b1 (recess) and the group of the holes 14a1 (recesses) at the outer edge of the part in the region AR1. Mechanical strength of the glass substrate 11 and sufficient tightening strength are retained by the region AR2 other than the region AR2 where the damage 15 occurs in the region AR1.

In this way, in the circuit board 10, the step 14a in which the group of the holes 14a1 is arranged along the outer edge of the region AR1 surrounding the through-hole 13 of the glass substrate 11 is formed. The step 14b in which the group of the grooves 14b1 is extended along the direction from the through-hole 13 to the step 14a is formed on the inside of the region AR1. Consequently, a concentrating region of stress generated in the glass substrate 11 when the screw 30 is tightened and an occurrence region of the damage 15 are adjusted. The damage 15 that occurs in the region AR1 is stopped from extending to the outside of the region AR1. As a result, the damage 15 is stopped from extending to the wire 12 formed outside the region AR1 on the glass substrate 11. Occurrence of a crack and disconnection of the wire 12 and occurrence of a resistance increase and an open failure due to the crack and the disconnection are reduced. Further, an occurrence region of the damage 15 in the region AR1 is adjusted. Occurrence of strength insufficiency and a fixing failure in the other regions is reduced. The circuit board 10 having high performance and reliability is realized. Further, the electronic device 1 having high performance and reliability including such a circuit board 10 is realized.

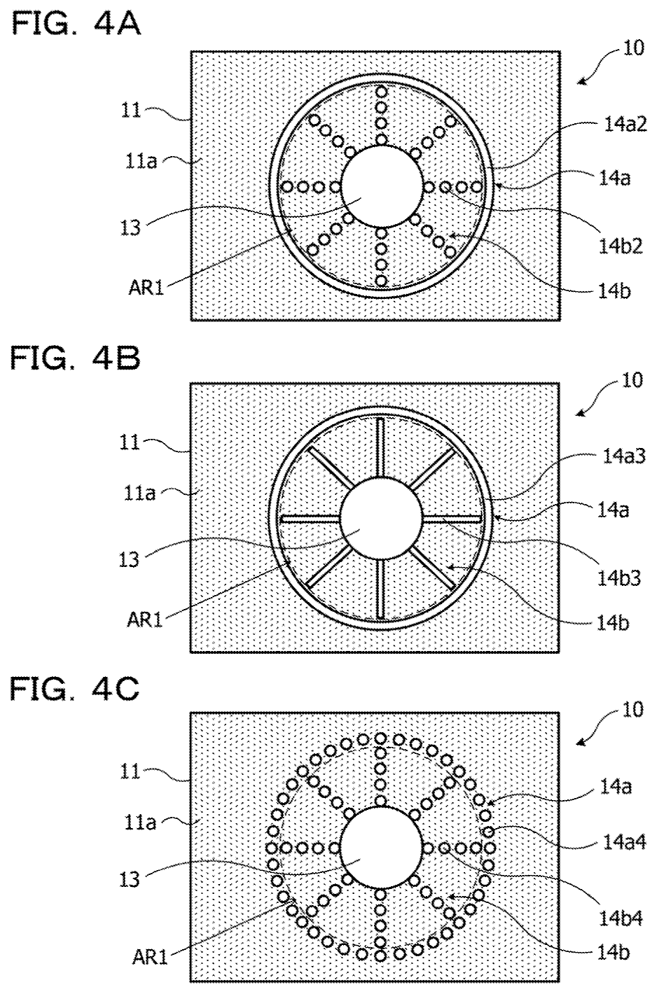

In FIG. 2A to 3B, as an example, the circuit board 10 is illustrated in which the step 14a including the group of the holes 14a1 arranged along the outer edge of the region AR1 and the step 14b including the group of the grooves 14b1 extended along the direction from the through-hole 13 to the step 14a in the region AR1 are formed. Besides, the step 14a and the step 14b illustrated in FIGS. 4A to 4C referred to below may be formed in the circuit board 10.

FIGS. 4A to 4C are diagrams illustrating modifications of the step of the circuit board according to the first embodiment. In FIGS. 4A to 4C, main part plan views of examples of the circuit board are respectively schematically illustrated.

The step 14a formed at the outer edge of the region AR1 of the circuit board 10 illustrated in FIG. 4A includes a groove 14a2 extended along the outer edge of the region AR1 and includes a step formed by the groove 14a2. The step 14b formed on the inside of the region AR1 of the circuit board 10 illustrated in FIG. 4A includes a plurality of holes 14b2 radially arranged along a direction from the through-hole 13 to the step 14a at the outer edge of the region AR1 and includes steps formed by groups of the holes 14b2.

The step 14a formed at the outer edge of the region AR1 of the circuit board 10 illustrated in FIG. 4B includes a groove 14a3 extended along the outer edge of the region AR1 and includes a step formed by the groove 14a3. The step 14b formed on the inside of the region AR1 of the circuit board 10 illustrated in FIG. 4B includes a plurality of grooves 14b3 radially extended along a direction from the through-hole 13 to the step 14a at the outer edge of the region AR1 and includes steps formed by groups of the grooves 14b3.

The step 14a formed at the outer edge of the region AR1 of the circuit board 10 illustrated in FIG. 4C includes a plurality of holes 14a4 arranged along the outer edge of the region AR1 and includes a step formed by a group of the holes 14a4. The step 14b formed on the inside of the region AR1 of the circuit board 10 illustrated in FIG. 4C includes a plurality of holes 14b4 radially arranged along a direction from the through-hole 13 to the step 14a at the outer edge of the region AR1 and includes steps formed by groups of the holes 14b4.

In the circuit board 10 illustrated in FIGS. 4A to 4C, a crack and a break easily occur in a row of a group of the holes 14b2 (FIG. 4A), the grooves 14b3 (FIG. 48), and a row of a group of the holes 14b4 (FIG. 4C) in the region AR1 with which the screw 30 comes into contact when the screw 30 is tightened. Extension of the crack and the break to the outside of the region AR1 is stopped by the groove 14a2 (FIG. 4A), the groove 14a3 (FIG. 4B), and a group of the holes 14a4 (FIG. 4C). Consequently, occurrence of a crack and disconnection of the wire 12 formed outside the region AR1 on the glass substrate 11 and occurrence of a resistance increase and an open failure due to the crack and the break are reduced. Further, an occurrence region of a crack and a break in the region AR1 is adjusted and occurrence of strength insufficiency and a fixing failure in the other regions is reduced. When the step 14a and the step 14b illustrated in FIGS. 4A to 4C are formed, it is possible to realize the circuit board 10 having high performance and reliability and the electronic device 1 including the circuit board 10.

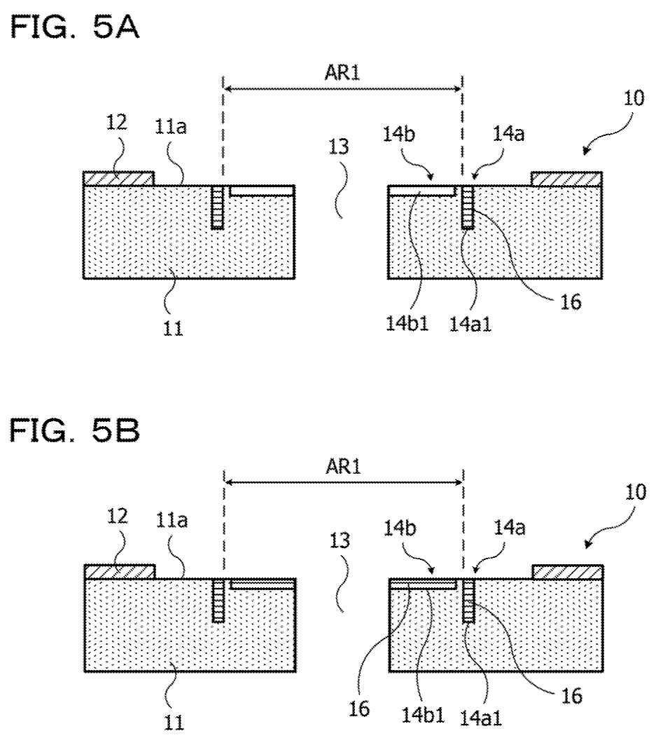

A configuration illustrated in FIGS. 5A and 5B referred to below may be adopted in the circuit board 10.

FIGS. 5A and 5B are diagrams illustrating a first configuration example of the circuit board according to the first embodiment. In FIGS. 5A and 5B, main part sectional views of examples of the circuit board are respectively illustrated.

The recess, for example, the group of the holes 14a1 (FIGS. 2A to 3B) included in the step 14a at the outer edge of the region AR1 of the circuit board 10 may be filled with a filling material 16 as illustrated in FIG. 5A. As the filling material 16, for example, a rein material or a mixture of the resin material and an inorganic or organic filler is used. When the holes 14a1 are filled by such a filling material 16, a crack and a break in the step 14a less easily occur. Strength deterioration of the circuit board 10 is reduced.

Further, the recesses, for example, the group of the grooves 14b1 (FIGS. 2A to 3B) formed in the step 14b on the inside of the region AR1 of the circuit board 10 may also be filled by the filling material 16 as illustrated in FIG. 5B. Consequently, a crack and a break in the step 14b less easily occur. Strength deterioration of the circuit board 10 is reduced.

In FIGS. 5A and 5B, the group of the holes 14a1 and the group of the grooves 14b1 are illustrated as the example. However, as explained above, the filling material 16 may be filled in the various recesses included in the step 14a of the circuit board and the various recesses included in the step 14b. Consequently, it is possible to obtain the same effects as the effects explained above.

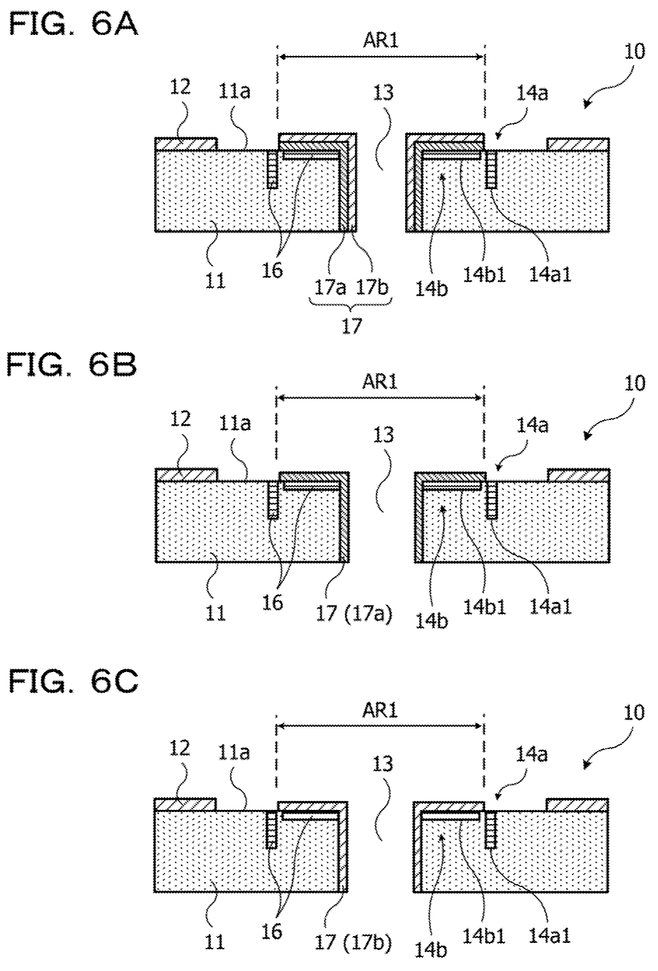

A configuration illustrated in FIGS. 6A to 6C referred to below may be adopted in the circuit board 10.

FIGS. 6A to 6C are diagrams illustrating a second configuration example of the circuit board according to the first embodiment. Main part sectional views of examples of the circuit board are respectively schematically illustrated in FIGS. 6A to 6C.

In the circuit board 10, a reinforcing layer 17 illustrated in FIGS. 6A to 6C may be formed on the inner surface of the through-hole 13 of the glass substrate 11. The reinforcing layer 17 may be extended from the inside of the through-hole 13 onto a predetermined region (for example, the region AR1) surrounding the through-hole 13 on the upper surface 11a of the glass substrate 11. In FIGS. 6A to 6C, an example is illustrated in which the filling material 16 (FIGS. 5A and 5B) is filled in the group of the grooves 14b1 and group of the holes 14a1 of the glass substrate 11. However, a part of the reinforcing layer 17 extended from the inside of the through-hole 13 to the upper surface 11a of the glass substrate 11 may be filled in the group of the grooves 14b1 and the group of the holes 14a1. The reinforcing layer 17 may be formed over the entire inner surface of the through-hole 13 or may be formed in a part of the inner surface of the through-hole 13. The reinforcing layer 17 may be formed on an entire predetermined region surrounding the through-hole 13 on the upper surface 11a of the glass substrate 11 or may be formed in a part on the region.

The reinforcing layer 17 is formed, for example, in a laminated structure of a resin layer 17a and the metal layer 17b illustrated in FIG. 6A. In the resin layer 17a, any one of various resin materials such as thermosetting, thermoplastic, and photocurable resin materials is used. For example, in the resin layer 17a, epoxy resin or polyimide resin are used. In the resin layer 17a, it is desirable to use a resin material having a lower modulus of elasticity than the glass substrate 11. Any one of various metal materials is used in the metal layer 17b. For example, in the metal layer 17b, copper, silver, tin, nickel, bismuth, indium, antimony, or gold or an alloy containing at least one kinds of these kinds of metal is used.

Since the reinforcing layer 17 is formed on the inner surface of the through-hole 13 that pierces through the glass substrate 11, improvement of the strength near the through-hole 13 of the glass substrate 11, improvement of the strength of a part with which the screw 30 inserted through the through-hole 13 comes into contact, mitigation of stress caused by the contact of the screw 30 inserted through the through-hole 13, and the like are achieved. Consequently, occurrence of a crack and a break of the glass substrate 11 is reduced.

In FIG. 6A, the example is illustrated in which the laminated structure of the resin layer 17a and the metal layer 17b is formed as the reinforcing layer 17. However, of the resin layer 17a and the metal layer 17b, as illustrated in FIG. 6B, only the resin layer 17a may be formed as the reinforcing layer 17. Besides, of the resin layer 17a and the metal layer 17b, as illustrated in FIG. 6C, only the metal layer 17b may be formed as the reinforcing layer 17. Even if the reinforcing layer 17 illustrated in FIGS. 6B and 6C is formed, the same effects may be obtained.

The reinforcing layer 17 may be formed from the inner surface of the through-hole 13 to the upper surface 11a of the glass substrate 11. Besides, the reinforcing layer 17 may also be formed only on the inner surface of the through-hole 13 or only on the upper surface 11a of the glass substrate 11. Even if the reinforcing layer 17 is formed only on the inner surface of the through-hole 13, it is possible to achieve improvement of the strength near the through-hole 13 of the glass substrate 11, improvement of the strength of a part with which the screw 30 inserted through the through-hole 13 comes into contact, mitigation of stress caused by the contact of the screw 30, and the like. Even if the reinforcing layer 17 is formed only on the upper surface 11a of the glass substrate 11, it is possible to achieve improvement of the strength near the through-hole 13 of the glass substrate 11, mitigation of stress caused by the contact of the head 31 of the screw 30, and the like.

The configuration of the step 14a and the step 14b formed on the glass substrate 11 of the circuit board 10 is not limited to the example explained above.

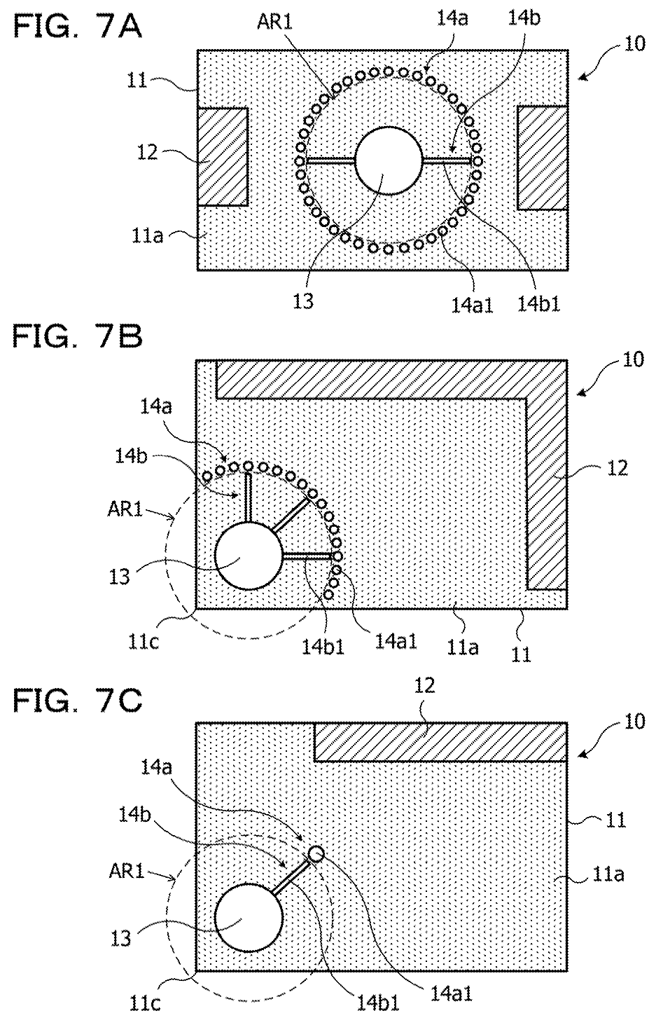

FIGS. 7A to 7C are diagrams illustrating a third configuration example of the circuit board according to the first embodiment. Main part sectional views of examples of the circuit board are respectively illustrated in FIGS. 7A to 7C.

For example, as explained above with reference to FIGS. 2A and 2B and the like, when the holes 14a1 are formed in the step 14a of the glass substrate 11 and the grooves 14b1 are formed in the step 14b, the numbers and disposition of the holes 14a1 and the grooves 14b1 may be set based on a layout of the wire 12 on the glass substrate 11.

In the example illustrated in FIG. 7A, the group of the holes 14a1 is arranged along the outer edge of the region AR1 surrounding the through-hole 13 of the glass substrate 11. The group of a pair of the grooves 14b1 are extended on the inside of the region AR1 to be opposed to each other across the through-hole 13. The wires 12 are respectively disposed on extended lines of the grooves 14b1. In the case of this example, even if the screw 30 inserted through the through-hole 13 comes into contact with the glass substrate 11 and a crack and a break occur in the group of the grooves 1461, the crack and the break are reduced from extending to the wires 12 by the group of the holes 14a1. An occurrence region of a crack and a break of the glass substrate 11 is each of regions such as an upper half illustrated in FIG. 7A and a lower half illustrated in FIG. 7B across the group of the pair of the groove 14b1 in the region AR1 surrounded by the group of the holes 14a1. As in this example, the group of the grooves 14b1 may be selectively formed in positions where the wires 12 are laid out on the extended lines of the group of the grooves 14b1 of the glass substrate 11.

In the example illustrated in FIG. 7B, the through-hole 13 is formed near a corner 11c of the glass substrate 11. The group of the holes 14a1 is arranged along the outer edge of the region AR1 surrounding the through-hole 13. A group of three grooves 14b1 is extended from the through-hole 13 toward the group of the holes 14a1 on the inside of the region AR1. A continuously extended L-shaped wire 12 is disposed on extended lines of the group of the grooves 14b1 of the glass substrate 11. In the case of this example, even if the screw 30 inserted through the through-hole 13 comes into contact with the glass substrate 11 and a crack and a break occur in the group of the grooves 14b1, the crack and the break are reduced from extending to the wire 12 by the group of the holes 14a1. As in this example, the group of the grooves 14b1 may be formed in positions where the wire 12 are laid out on the extended lines. The holes 14a1 are not required to be formed over the entire circumference of the through-hole 13.

In the example illustrated in FIG. 7C, the through-hole 13 is formed near the corner 11c of the glass substrate 11, one groove 14b1 is formed on the inside of the region AR1 from the through-hole 13 toward the wire 12. One hole 14a1 is formed at the distal end of the groove 14b1. That is, for example, the hole 14a1 and the wire 12 are disposed on an extended line of the groove 14b1. Even in such a case, even if the screw 30 inserted through the through-hole 13 comes into contact with the glass substrate 11 and a crack and a break occur in the groove 14b1, the crack and the break are reduced from extending to the wire 12 by the hole 14a1.

As illustrate in FIGS. 7A to 7C, the numbers and disposition of the holes 14a1 and the grooves 14b1 may be set based on a layout of the wire 12 formed on the glass substrate 11.

The example is explained in which the hole(s) 14a1 is formed in the step 14a at the outer edge of the region AR1 and the groove(s) 14b1 is formed in the step 14b on the inside of the region AR1. Besides, when grooves are formed in the step 14a, extending positions and extending lengths of the grooves may be set based on the layout of the wire(s) 12. When a group of holes is formed in the step 14b, an arraying direction and disposition positions of the group of holes may be set based on the layout of the wire(s) 12.

The method explained as the first embodiment is not limited to the circuit board 10 in which the glass substrate 11 is used as the insulating base material of the circuit board 10. The method may also be adopted in circuit boards in which substrates of various fragile materials such as a silicon substrate, a sapphire substrate, and a ceramic substrate are used in a part of or the entire circuit boards.

A second embodiment is explained.

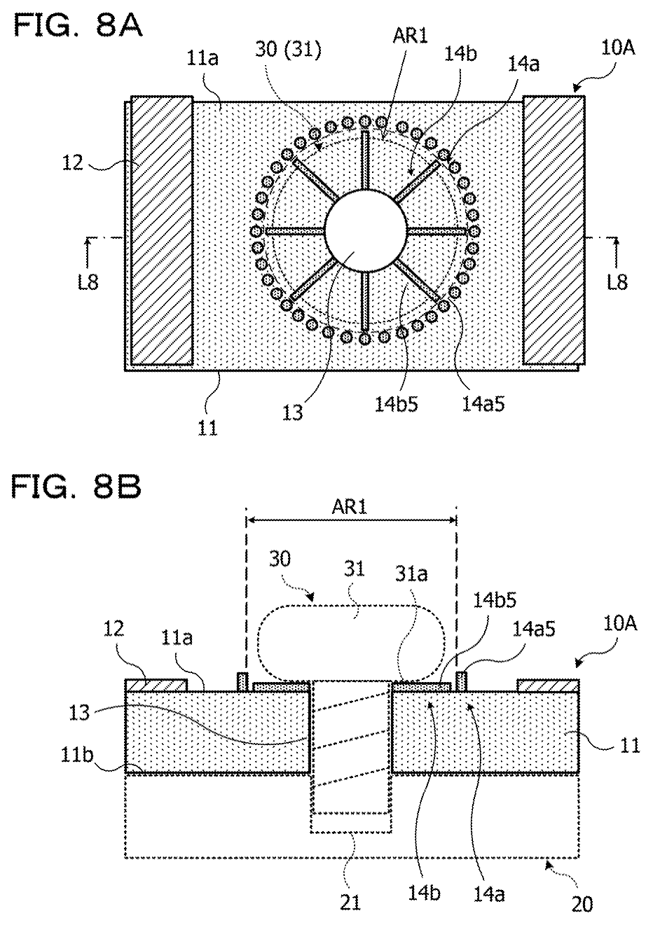

FIGS. 8A and 8B are diagrams illustrating an example of a circuit board according to the second embodiment. In FIG. 8A, a main part plan view of the example of the circuit board is schematically illustrated. In FIG. 8B, a main part sectional view of the example of the circuit board is schematically illustrated. FIG. 8B is a IIIB-IIIB sectional schematic diagram of FIG. 8A. In FIGS. 8A and 88B, for convenience, a supporting body that fixes the circuit board and a screw for fixing the circuit board to the supporting body are respectively indicated by dotted lines.

A circuit board 10A illustrated in FIGS. 8A and 8B includes a step 14a including a plurality of protrusions 14a5 arranged along the outer edge of the region AR1 surrounding the through-hole 13 of the glass substrate 11. The circuit board 10A further includes, on the inside of the region AR1 surrounding the through-hole 13 of the glass substrate 11, a step 14b including a plurality of protrusions 14b5 extended along a direction from the through-hole 13 to the outer edge of the region AR1. The circuit board 10A is different from the circuit board 10 explained in the first embodiment in that the circuit board 10A includes the step 14a and the step 14b. As in the circuit board 10A, the step 14a and the step 14b may include steps formed by a group of the protrusions 14a5 and a group of the protrusions 14b5 (projections) formed on the glass substrate 11.

The group of the protrusions 14a5 and the group of the protrusions 14b5 are formed, for example, as a part of the glass substrate 11. Such a glass substrate 11 including the group of the protrusions 14a5 and the group of the protrusions 14b5 is formed by, for example, machining a surface layer section of sheet glass serving as the glass substrate 11 by a laser, etching, or the like. The group of the protrusions 14a5 and the group of the protrusions 14b5 are desirably formed to have height equal to or larger than a microcrack that occurs in the glass substrate 11 (for example, height equal to or larger than 0.5 μm). When the group of the protrusions 14a5 and the group of the protrusions 14b5 are set to such height, a crack and a break easily occur around (recesses around) the protrusions 14a5 and the protrusions 14b5. Extension of the crack and the break to the outer side of the region AR1 less easily occurs.

The circuit board 10A having the configuration explained above is fixed to the supporting body 20 by the screw 30 to form an electronic device. When the circuit board 10A is tightened to the supporting body 20 by the screw 30, the lower surface 31a of the screw 30 comes into contact with the protrusions 14b5 of the step 14b formed in the region AR1 of the glass substrate 11. At this time, relatively large stress is generated in a region near the through-hole 13 on the glass substrate 11. By the stress generated when the screw 30 is tightened, a crack and a break are easily caused from the protrusions 14b5 of the step 14b, for example, the edges of roots where the protrusions 14b5 stand. The crack and the break are easily led and extend toward the outside of the through-hole 13. In the circuit board 10A, such extension of the crack and the break is stopped (terminated) by at least one protrusion 14a5 of the step 14a formed at the outer edge of the region AR1, for example, by the edge of a root where the protrusion 14a5 stands. Further extension to the outer side than the step 14a is stopped.

In the circuit board 10A, a crack and a break easily occur in each of regions surrounded by a part (a recess) sandwiched by the group of a pair of the protrusions 14b5 (projections) and the group of the protrusions 14a5 (projection) at the outer edge of the part in the region AR1. Mechanical strength of the glass substrate 11 and sufficient tightening strength are retained by regions other than the region where the crack and the break occur in the region AR1.

In this way, in the circuit board 10A, the step 14a in which the group of the protrusions 14a5 is arranged along the outer edge of the region AR1 is formed. In the region AR1, the step 14b in which the group of the protrusions 14b5 is extended along the direction from the through-hole 13 to the step 14a is formed. Consequently, a concentrating region of stress generated in the glass substrate 11 when the screw 30 is tightened and an occurrence region of a crack and a break are adjusted. A crack and a break that occur in the region AR1 are stopped from extending to the outside of the region AR1. As a result, the crack and the break are stopped from extending to the wire 12 formed outside the region AR1 on the glass substrate 11. Occurrence of a crack and disconnection of the wire 12 and occurrence of a resistance increase and an open failure due to the crack and the disconnection are reduced. Further, an occurrence region of a crack and a break in the region AR1 is adjusted. Occurrence of strength insufficiency and a fixing failure in regions other than the occurrence region is reduced. The circuit board 10A with high performance and reliability is realized. Further, an electronic device with high performance and reliability including the circuit board 10A is realized.

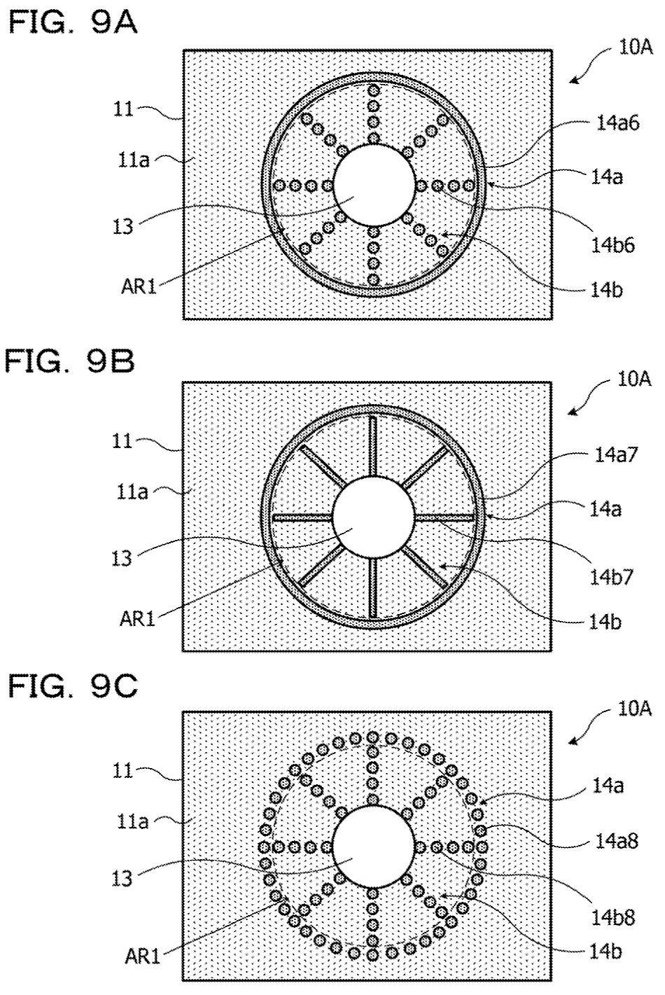

FIGS. 9A to 9C are diagrams illustrating a modification of the step of the circuit board according to the second embodiment. Main part plan views of examples of the circuit board are respectively schematically illustrated in FIGS. 9A to 9C.

The step 14a formed at the outer edge of the region AR1 of the circuit board 10A illustrated in FIG. 9A includes a protrusion 14a6 extended along the outer edge of the region AR1 and includes a step formed by the protrusion 14a6. A step 14b formed on the inside of the region AR1 of the circuit board 10A illustrated in FIG. 9A includes groups of protrusions 14b6 radially arranged along a direction from the through-hole 13 to the step 14a at the outer edge of the region AR1 and includes steps formed by the groups of the protrusions 14b6.

The step 14a formed at the outer edge of the region AR1 of the circuit board 10A illustrated in FIG. 9B includes a protrusion 14a7 extended along the outer edge of the region AR1 and includes a step formed by the protrusion 14a7. The step 14b formed on the inside of the region AR1 of the circuit board 10A illustrated in FIG. 9B includes groups of protrusions 14b7 radially extended along a direction from the through-hole 13 to the step 14a at the outer edge of the region AR1 and includes steps formed by the groups of the protrusions 14b7.

The step 14a formed at the outer edge of the region AR1 of the circuit board 10A illustrated in FIG. 9C includes a group of protrusions 14a8 arranged along the outer edge of the region AR1 and includes a step formed by the group of the protrusions 14a8. The step 14b formed on the inside of the region AR1 of the circuit board 10A illustrated in FIG. 9C includes groups of protrusions 14b8 radially arranged along a direction from the through-hole 13 to the step 14a at the outer edge of the region AR1 and includes steps formed by the groups of the protrusions 14b8.

In the circuit board 10A illustrated in FIGS. 9A to 9C, a crack and a break easily occur in a row of a group of the protrusions 14b6 (FIG. 9A), the protrusions 14b7 (FIG. 9B), and a row of a group of the protrusions 14b8 (FIG. 9C) in the region AR1 with which the screw 30 comes into contact when the screw 30 is tightened. Extension of the crack and the break to the outside of the region AR1 is stopped by the protrusion 14a6 (FIG. 9A), the protrusion 14a7 (FIG. 9B), and the group of the protrusions 14a8 (FIG. 9C). Consequently, occurrence of a crack and disconnection of the wire 12 formed outside the region AR1 on the glass substrate 11 and occurrence of a resistance increase and an open failure due to the crack and the break are reduced. Further, an occurrence region of a crack and a break in the region AR1 is adjusted. Occurrence of strength insufficiency and a fixing failure in regions other than the occurrence region is reduced. When the step 14a and the step 14b illustrated in FIGS. 9A to 9C are formed, it is possible to realize the circuit board 10A with high performance and reliability and an electronic device including the circuit board 10A.

The region AR1 is not limited to a circular shape in a plan view and may be formed in various shapes as long as the region AR1 surrounds the through-hole 13.

The method explained as the second embodiment is not limited to the circuit board 10A in which the glass substrate 11 is used as the insulating base material of the circuit board 10A. The method may also be adopted in circuit boards in which substrates of various fragile materials such as a silicon substrate, a sapphire substrate, and a ceramic substrate are used in a part of or the entire circuit boards.

A third embodiment is explained.

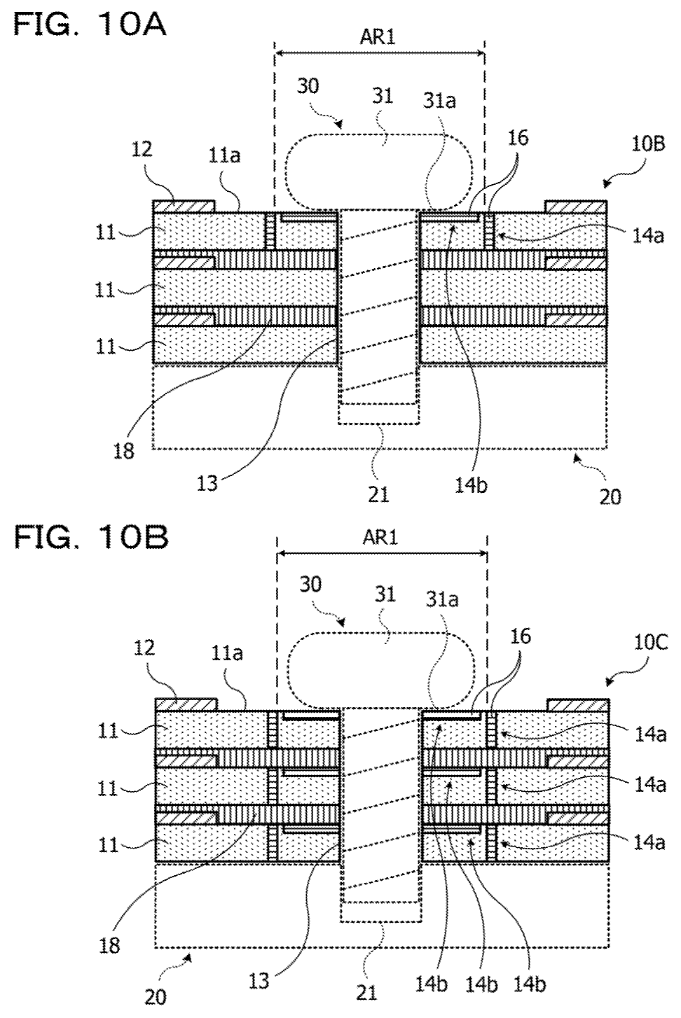

FIGS. 10A and 10B are diagrams illustrating an example of a circuit board according to the third embodiment. In FIG. 10A, a main part sectional view of a first example of the circuit board is schematically illustrated. In FIG. 10B, a main part sectional view of a second embodiment of the circuit board is schematically illustrated. In FIGS. 10A and 10B, for convenience, a supporting body that fixes the circuit board and a screw for fixing the circuit board to the supporting body are respectively indicated by dotted lines.

A circuit board 10B illustrated in FIG. 10A is a so-called multilayer glass substrate that has structure in which a plurality of (as an example, three) glass substrates 11 are stacked via adhesive layers 18. The wires 12 are formed on the glass substrates 11. The through-holes 13 formed in corresponding positions of the glass substrates 11 communicate and function as one through-hole 13 that pierces through a stacked group of the glass substrates 11. In the circuit board 10B, the step 14a and the step 14b are formed on only the glass substrate 11 in the top layer in the stacked group of the glass substrates 11. In FIG. 10A, as the step 14a and the step 14b, steps formed by the holes or the grooves explained in the first embodiment or a combination of the holes and the grooves are illustrated. The filling material 16 (FIGS. 5A and 5B) may be filled in recess of the step 14a and the step 14b of the circuit board 10B.

In the circuit board 10B, the step 14a and the step 14b are formed on the glass substrate 11 in the top layer with which the screw 30 inserted into the through-hole 13, which pierces through the group of the glass substrates 11, comes into contact and in which a crack and a break most easily occur. Consequently, a concentrating region of stress generated in the glass substrate 11 in the top layer when the screw 30 is tightened and an occurrence region of a crack and a break are adjusted. A crack and a break that occur in the region AR1 are stopped from extending to the outside of the region AR1. As a result, the crack and the break are stopped from extending to the wire 12 formed outside the region AR1 on the glass substrate 11 in the top layer. Occurrence of a crack and disconnection of the wire 12 and occurrence of a resistance increase and an open failure due to the crack and the disconnection are reduced. Further, on the glass substrate 11 in the top layer, an occurrence region of a crack and a break in the region AR1 is adjusted. Occurrence of strength insufficiency and a fixing failure in regions other than the occurrence region is reduced. The circuit board 10B with high performance and reliability is realized. Further, an electronic device with high performance and reliability including the circuit board 10B is realized.

A circuit board 10C illustrated in FIG. 10B is different from the circuit board 10B illustrated in FIG. 10A in that the steps 14a and the steps 14b are formed on all of the stacked glass substrates 11. The filling material 16 (FIGS. 5A and 5B) may be filled in the recesses of the step 14a and the step 14b of the group of the glass substrates 11. The filling material 16 may be a part of the adhesive layers 18 that bond the glass substrates 11. In the circuit board 10C, the recesses of the steps 14a and the steps 14b of the group of the glass substrates 11 may be formed, for example, in positions corresponding each other. In the circuit board 10C, the recesses of the steps 14a and the steps 14b of the group of the glass substrates 11 may be formed in positions not corresponding to each other. In this way, parts that easily become start points of a crack and a break of the group of the glass substrates 11 may be shifted to increase the strength near the through-hole 13.

In the circuit board 10C, besides the glass substrate 11 in the top layer with which the screw 30 comes into contact, the steps 14a and the steps 14b are also formed in the group of the glass substrates 11 in lower layers under the top layer. Consequently, even if a crack and a break occur in the region AR1 of the group of the glass substrates 11 in the lower layers when the screw 30 is tightened, extension of the crack and the break to the outside of the region AR1 of the glass substrates 11 in the lower layers and occurrence of a crack and disconnection of the wire 12 due to the extension of the crack and the break are reduced. Further, in the glass substrates 11, an occurrence region of a crack and a break in the region AR1 is adjusted. Strength insufficiency and a fixing failure in regions other than the occurrence region is reduced. The circuit board 10C with high performance and reliability is realized. Further, an electronic device having high performance and reliability including such a circuit board 10C is realized.

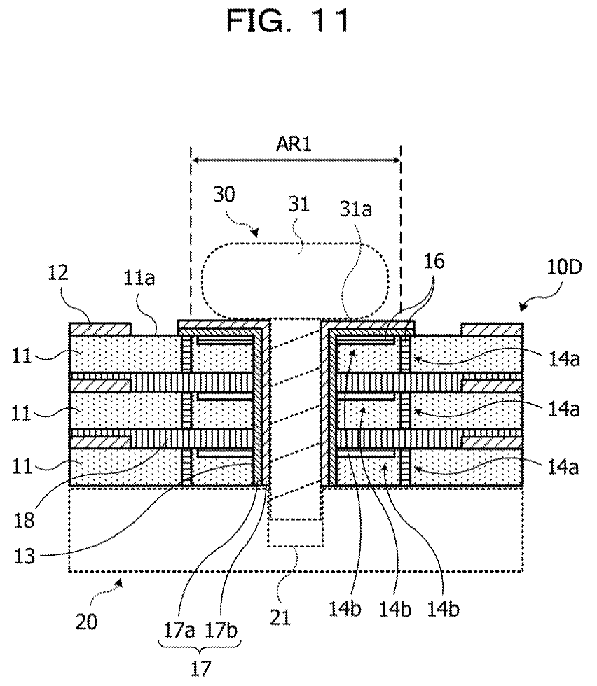

FIG. 11 is a diagram illustrating another example of the circuit board according to the third embodiment. In FIG. 11, a main part sectional view of the other example of the circuit board is schematically illustrated. In FIG. 11, for convenience, a supporting body that fixes the circuit board and a screw for fixing the circuit board to the supporting body are indicated by dotted lines.

A circuit board 10D illustrated in FIG. 11 is different from the circuit board 10C illustrated in FIG. 10B in that the reinforcing layer 17 is formed on the inner surface of the through-hole 13 that pierces through the group of the glass substrates 11. The reinforcing layer 17 may be extended from the inside of the through-hole 13 onto a predetermined region surrounding the through-hole 13 on the upper surface 11a of the glass substrate 11 in the top layer. The filling material 16 (FIGS. 5A and 5B) may be filled in the recesses of the steps 14a and the steps 14b of the group of the glass substrates 11. The filling material 16 may be a part of the adhesive layer 18 that bonds the glass substrates 11. A part of the reinforcing layer 17 extended from the inside of the through-hole 13 onto the glass substrate 11 may be filled in the recesses of the steps 14a and the steps 14b of the group of the glass substrates 11. The reinforcing layer 17 may be formed over the entire inner surface of the through-hole 13 or may be formed in a part of the inner surface of the through-hole 13. The reinforcing layer 17 may be formed on an entire predetermined region surrounding the through-hole 13 on the upper surface 11a of the glass substrate 11 or may be formed in a part of the region.

In FIG. 11, as an example of the reinforcing layer 17, a reinforcing layer including the laminated structure of the resin layer 17a and the metal layer 17b Illustrated in FIG. 6A is illustrated. On the inner surface of the through-hole 13 of the group of the glass substrates 11, as the reinforcing layer 17, only one of the resin layer 17a and the metal layer 17b may be formed according to the examples illustrated in FIGS. 6B and 6C.

Since the reinforcing layer 17 is formed on the inner surface of the through-hole 13 that pierces through the group of the glass substrates 11, improvement of the strength near the through-hole 13 of the group of the glass substrates 11, improvement of the strength of a part with which the screw 30 inserted through the through-hole 13 comes into contact, mitigation of stress caused by the contact of the screw 30 inserted through the through-hole 13, and the like are achieved. Consequently, occurrence of a crack and a break of the glass substrate 11 is reduced.

The reinforcing layer 17 may also be formed on the inner surface of the through-hole 13 of the circuit board 10B illustrated in FIG. 10A. Consequently, the same effects as the effects explained above may be obtained.

In FIGS. 10A, 10B, and 11, as the step 14a and the step 14b of the glass substrate 11 included in the circuit boards 10B, 10C, and 10D (the mutilayer glass substrate), the steps formed by the holes or the grooves explained or a combination of the holes and the grooves explained in the first embodiment (FIGS. 2A to 4C and the like) are illustrated. Besides, a multilayer glass substrate adopting the steps formed by the protrusions explained in the second embodiment (FIGS. 8A to 9C) as the step 14a and the step 14b of the glass substrate 11 may also be realized.

The region AR1 is not limited to the circular shape in the plan view and may be formed in various shapes as long as the region AR1 surrounds the through-hole 13.

The method explained as the third embodiment is not limited to the circuit boards 10B, 10C, and 10D in which the glass substrate 11 is used as the insulating base material of the circuit boards 10B, 10C, and 10D. The method may also be adopted in circuit boards in which substrates of various fragile materials such as a silicon substrate, a sapphire substrate, and a ceramic substrate are used in a part of or the entire circuit boards.

A fourth embodiment is explained.

An example of an analysis result of stress generated in a circuit board is explained as the fourth embodiment.

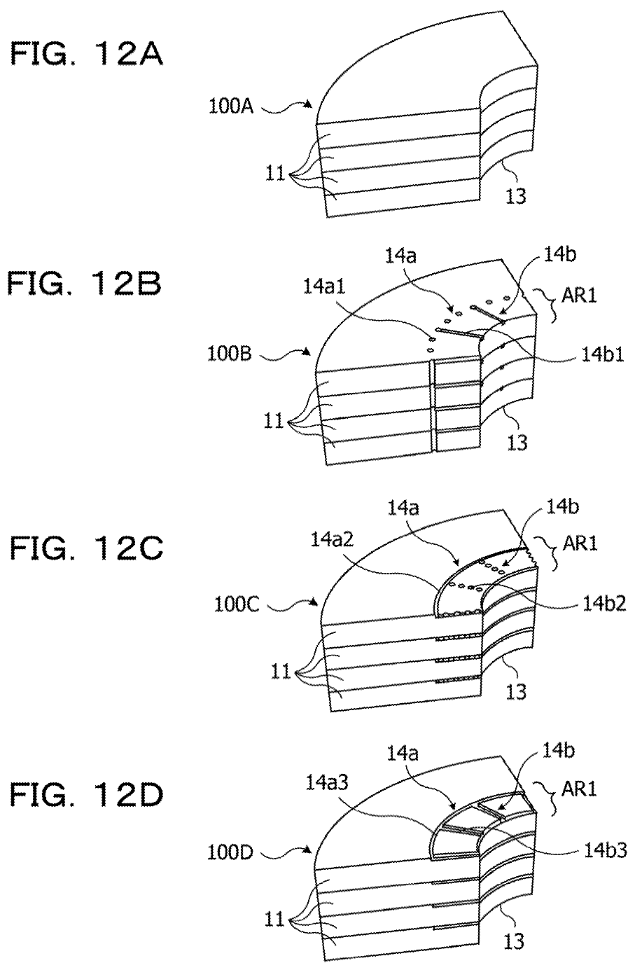

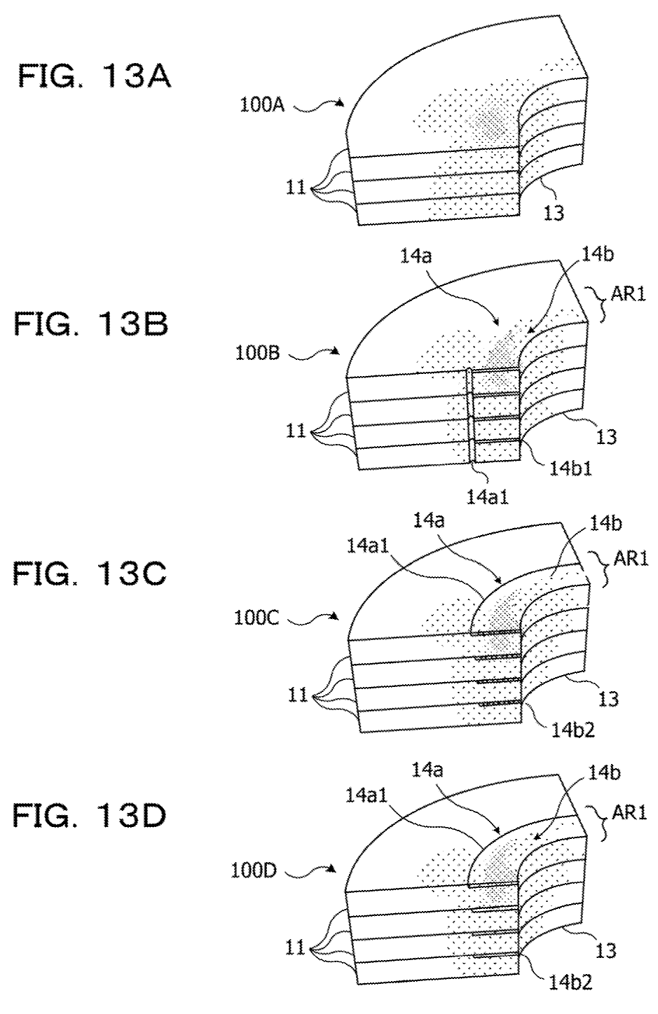

FIGS. 12A to 13D are explanatory diagrams of a stress analysis according to the fourth embodiment. Main part perspective views of models used for the stress analysis are respectively illustrated in FIGS. 12A to 12D. Stress analysis results obtained using the models illustrated in FIGS. 12A to 12D are respectively illustrated in FIGS. 13A to 13D.

In FIGS. 12A to 12D, models 100A, 100B, 100C, and 100D of a multilayer glass substrate in which a group of four glass substrates 11 are stacked are illustrated as models of the circuit board.

The model 100A illustrated in FIG. 12A has structure in which the group of the glass substrates 11 in which the step 14a and the step 14b explained above are not formed are stacked.

The model 100B illustrated in FIG. 12B has structure including the step 14a including the group of the holes 14a1 arranged along the outer edge of the region AR1 surrounding the through-hole 13 and the step 14b including the group of the grooves 14b1 extended from the through-hole 13 toward the step 14a on the inside of the region AR1. This model 1008 is a model in which the step 14a and the step 14b illustrated in FIGS. 2A and 2B are adopted in the multilayer glass substrate.

The model 100C illustrated in FIG. 12C has structure including the step 14a Including the groove 14a2 extended along the outer edge of the region AR1 surrounding the through-hole 13 and the steps 14b including the group of the holes 14b2 arranged from the through-hole 13 toward the step 14a on the inside of the region AR1. This model 100C is a model in which the step 14a and the step 14b illustrated in FIG. 4A are adopted in the multilayer glass substrate.

The model 100D illustrated in FIG. 12D has structure including the step 14a including the groove 14a3 extended along the outer edge of the region AR1 surrounding the through-hole 13 and a step 14b including a group of the grooves 14b3 extended from the through-hole 13 toward the step 14a on the inside of the region AR1. This model 100D is a model in which the step 14a and the step 14b illustrated in FIG. 4B are adopted in the multilayer glass substrate.

Respective stress analysis results of the model 100A (FIG. 12A), the model 100B (FIG. 12B), the model 100C (FIG. 12C), and the model 100D (FIG. 12D) are respectively illustrated in FIGS. 13A, 13B, 13C, and 13D.

In the model 100A in which the step 14a and the step 14b are not formed in the group of the glass substrates 11, as illustrated in FIG. 13A, stress generated when a force equivalent to tightening of the screw 30 is applied spreads to a relatively wide range. On the other hand, in the model 100B, the model 100C, and the model 100D in which the step 14a and the step 14b are formed in the group of the glass substrates 11, the stress generated when such a force is applied concentrates on the region AR1 relatively further on the inner side than the step 14a at the outer edge of the region AR1. The spread of the stress may be reduced.

By forming the step 14a and the step 14b in the group of the glass substrates 11 in this way, it is possible to adjust a concentrating region of the stress. Consequently, it is possible to adjust an occurrence region of a crack and a break and stop extension of the crack and the break to the outside of the region AR1.

A fifth embodiment is explained below.

An example of a method of forming a circuit board is explained as a fifth embodiment.

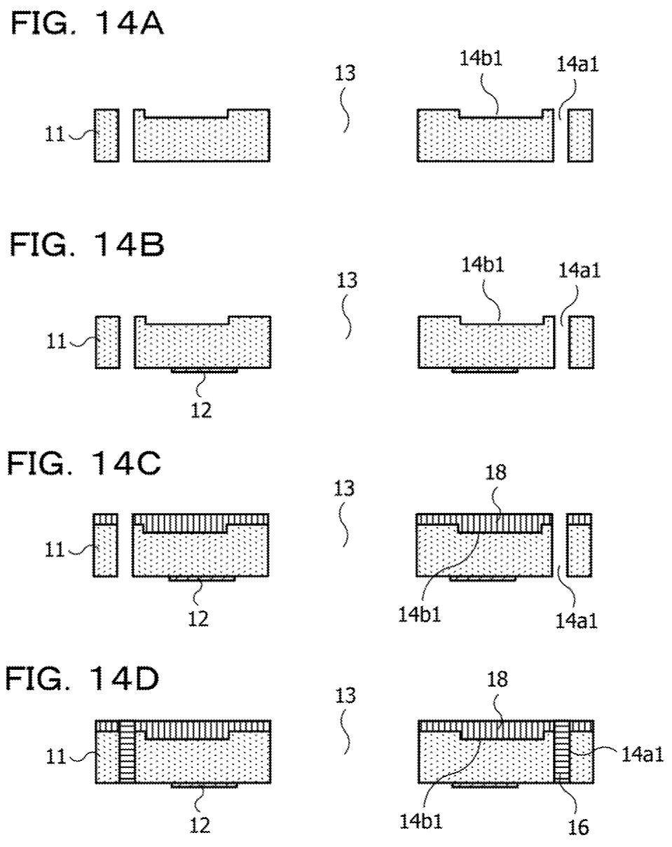

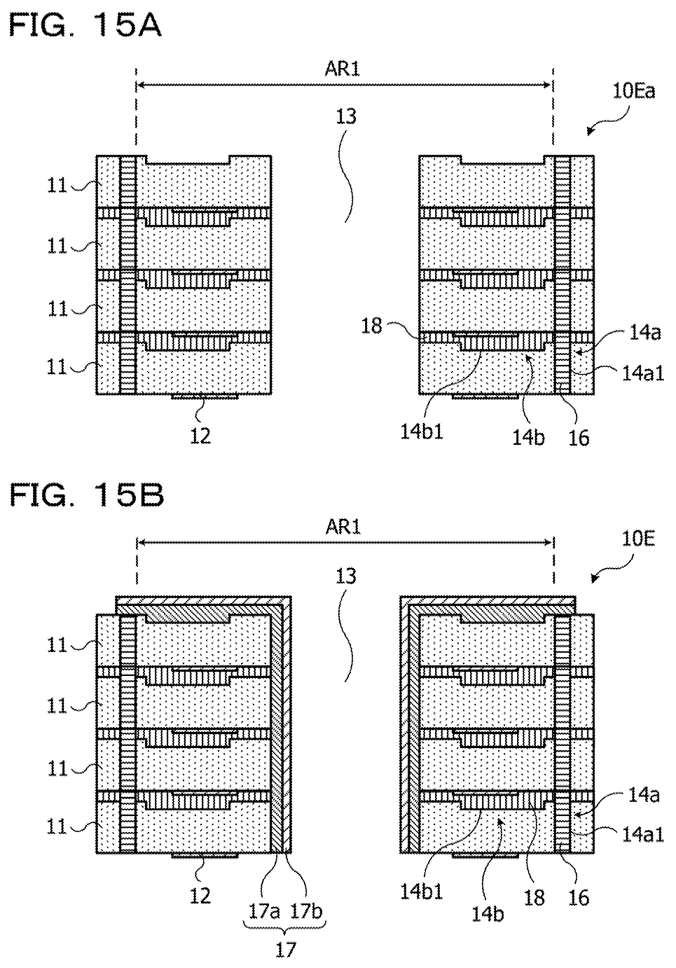

FIGS. 14A to 15B are diagrams illustrating a first example of the method of forming the circuit board according to the fifth embodiment. Main part sectional views of examples of a circuit board forming process are respectively schematically illustrated in FIGS. 14A to 14D and FIGS. 15A and 15B.

Formation of a multilayer glass substrate including the step 14a including group of the holes 14a1 formed at the outer edge of the region AR1 surrounding the through-hole 13 and the step 14b including the group of the grooves 14b1 extended from the through-hole 13 toward the step 14a in the region AR1 is explained as an example.

First, as illustrated in FIG. 14A, formation of the through-hole 13, formation of group of the holes 14a1, and formation of the group of the grooves 14b1 are performed on sheet glass to form the glass substrate 11. The order of the formation of the through-hole 13, the formation of group of the holes 14a, and the formation of the group of the grooves 14b1 is not limited. The through-hole 13, group of the holes 14a1, and the group of the grooves 14b1 are formed, for example, using a laser. Besides, the through-hole 13, group of the holes 14a1, and the group of the grooves 14b1 may be formed by processing such as etching, sand blast, or plasma or using a drill.

Subsequently, as illustrated in FIG. 14B, the wire 12 is formed on the glass substrate 11. The wire 12 is formed by a method such as patterning of conductor foil stuck on the glass substrate 11, patterning of a conductor layer deposited on the glass substrate 11, or plating of a conductor layer on a predetermined region of the glass substrate 11. A formation region of the wire 12 is not limited to an example illustrated in FIG. 14B. According to the glass substrates 11 to be stacked, the wire 12 is formed in a predetermined pattern shape in predetermined regions on both surfaces of the glass substrates 11.

Subsequently, as illustrated in FIG. 14C, an adhesive layer 18 is formed on the glass substrate 11. For example, a resin sheet formed by using epoxy resin, polyimide resin, or the like is laminated as the adhesive layer 18 on one surface (in this example, a surface on which the group of the grooves 14b1 is formed) of the glass substrate 11. Alternatively, as the adhesive layer 18, a resin material such as epoxy resin or polyimide resin or paste obtained by mixing such a resin material and a filler is applied. The adhesive layer 18 does not have to be formed on the glass substrate 11 in the top layer of the multilayer glass substrate.

Subsequently, as illustrated in FIG. 14D, the filling material 16 is filled in group of the holes 14a1 formed on the glass substrate 11. For example, a resin material such as epoxy resin or polyimide resin or paste obtained by mixing such a resin material and a filler is filled in group of the holes 14a1 as the filling material 16. When the paste applied as the adhesive layer 18 in the process of FIG. 14C explained above is the same material as the paste filled as the filling material 16 in the process of FIG. 14D, the paste may be formed on the glass substrate 11 and in group of the holes 14a1 to collectively form the adhesive layer 18 and the filling material 16.

Subsequently, the glass substrates 11 formed by the processes illustrated in FIGS. 14A to 14D are stacked as illustrated in FIG. 15A. The group of the glass substrates 11 is stuck together with the positions of the respectively through-holes 13 aligned and the adhesive layers 18 interposed among the glass substrates 11. For example, from such a state, heating or pressurizing or heating and pressurizing are performed to bond the group of the glass substrates 11.

A circuit board (a multilayer glass substrate) 10Ea including basic structure is formed by the processes of FIGS. 14A to 14D and FIG. 15A.

After the formation of such a circuit board 10Ea, as illustrated in FIG. 15B, the reinforcing layer 17 may be formed on the inner surface of the through-hole 13 of the group of the glass substrates 11. For example, as the reinforcing layer 17, the resin layer 17a extended from the inside of the through-hole 13 of the group of the glass substrates 11 onto the glass substrate 11 in the top layer is formed. The metal layer 17b is formed on the resin layer 17a. Consequently, a circuit board (a multilayer glass substrate) 10E in which the reinforcing layer 17 is further formed on the circuit board 10Ea is formed.

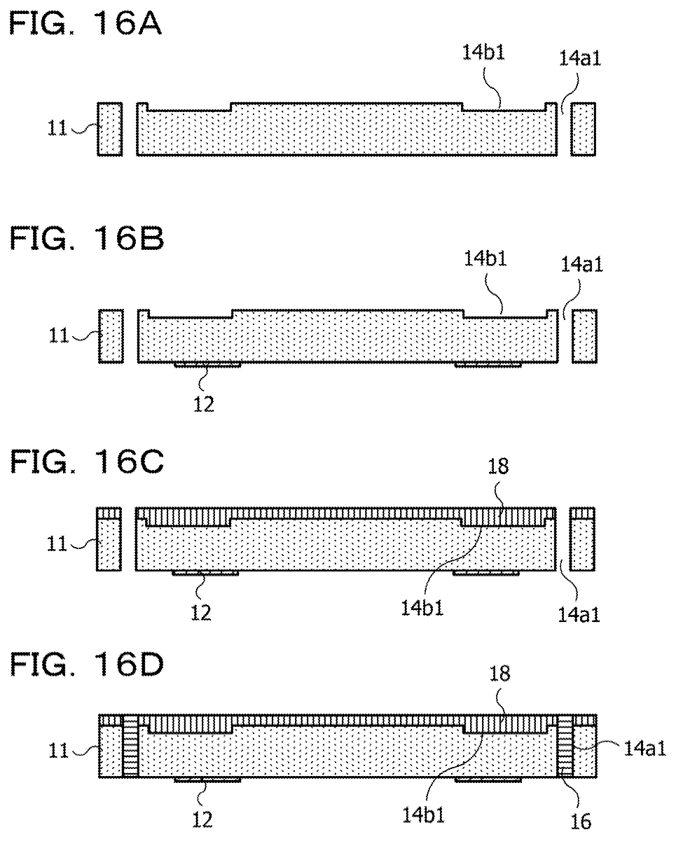

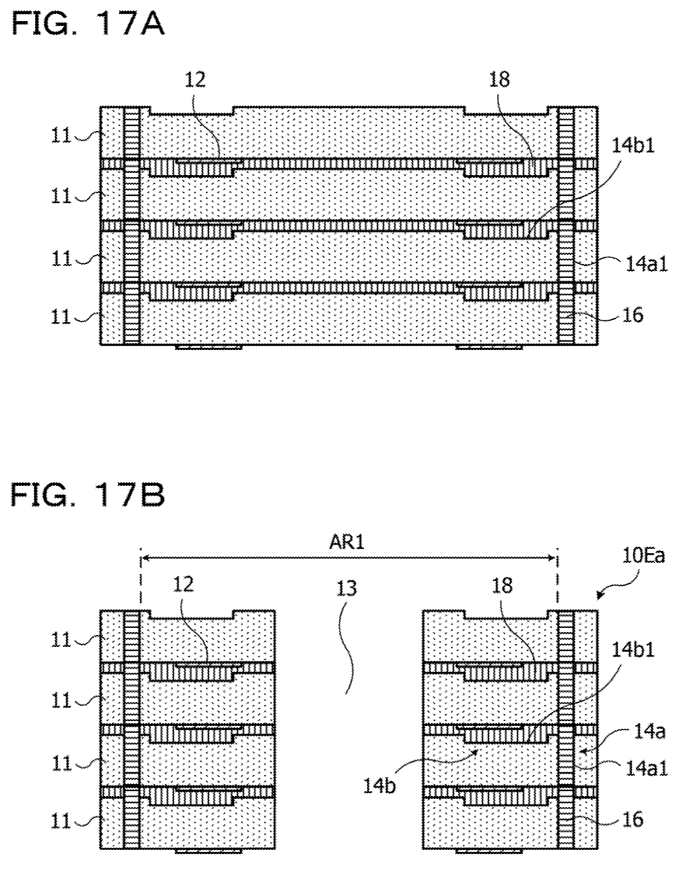

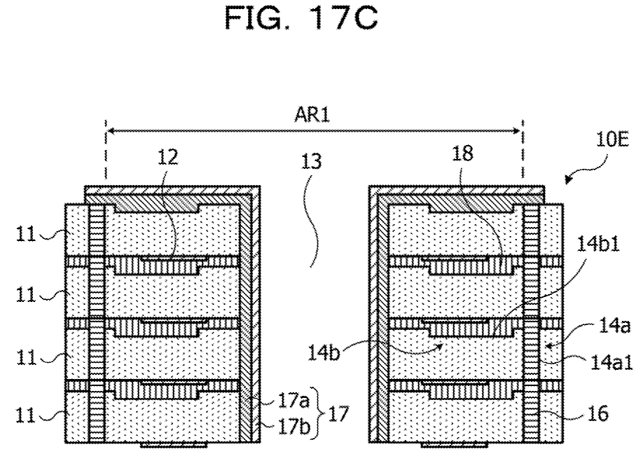

FIGS. 16A to 16D and 17A to 17C are diagrams illustrating a second example of the method of forming the circuit board according to the fifth embodiment. Main part sectional views of examples of a circuit board forming process are respectively schematically illustrated in FIGS. 16A to 16D and FIGS. 17A to 17C.

As in the forming method in the first example, formation of a multilayer glass substrate including the step 14a including group of the holes 14a1 formed at the outer edge of the region AR1 surrounding the through-hole 13 and the step 14b including the group of the grooves 14b1 extended from the through-hole 13 toward the step 14a in the region AR1 is explained as an example.

First, as illustrated in FIG. 16A, formation of group of the holes 14a1 and formation of the group of the grooves 14b1 are performed using a laser on sheet glass to form the glass substrate 11. The order of the formation of group of the holes 14a1 and the formation of the group of the grooves 14b1 is not limited.

Subsequently, as illustrated in FIG. 16B, the wire 12 is formed on the glass substrate 11. The wire 12 is formed in a predetermined pattern shape in predetermined regions on both surfaces of the stacked glass substrates 11 according to the stacked glass substrates 11.

Subsequently, as illustrated in FIG. 16C, the adhesive layer 18 is formed on the glass substrate 11 by laminate of a resin sheet or application of a resin material or paste.

Subsequently, as illustrated in FIG. 16D, the resin material or the paste is filled in group of the holes 14a1 formed on the glass substrate 11 to form the filling material 16. When paste of the same material is used for the adhesive layer 18 and the filling material 16, the paste may be formed on the glass substrate 11 and in group of the holes 14a1 to collectively form the adhesive layer 18 and the filling material 16.

Subsequently, the glass substrates 11 formed by the processes illustrated in FIGS. 16A to 16D are stacked as illustrated in FIG. 17A. The group of the glass substrates 11 is opposed and stuck together with the adhesive layers 18 interposed among the glass substrates 11. For example, heating or pressurizing or heating and pressurizing are performed from such a state to bond the group of the glass substrates 11.

Subsequently, as illustrated in FIG. 17B, the through-hole 13 that pierces through the bonded group of the glass substrates 11 is collectively formed. The through-hole 13 that pierces through the group of the glass substrates 11 is formed, for example, using a laser. Besides, the through-hole 13 may be collectively formed by processing such as etching, sand blast, or plasma or using a drill.

The circuit board (the multilayer glass substrate) 10Ea having basic structure is formed by the processes of FIGS. 16A to 16D and FIGS. 17A and 17B explained above.

After the formation of such a circuit board 10Ea, as illustrated in FIG. 17C, the reinforcing layer 17 may be formed on the inner surface of the through-hole 13 of the group of the glass substrates 11. For example, as the reinforcing layer 17, the resin layer 17a extended from the inside of the through-hole 13 of the group of the glass substrates 11 onto the glass substrate 11 in the top layer is formed. The metal layer 17b is formed on the resin layer 17a. Consequently, the circuit board 10E in which the reinforcing layer 17 is further formed on the circuit board 10Ea is formed.

As an example, the method of forming the circuit board 10Ea or the circuit board 10E including group of the holes 14a1 and the group of the grooves 14b1 is explained above. Besides, in the method explained above, if the shape and the disposition of the unevenness formed in the processes of FIGS. 14A and 16A are changed, circuit boards including the step 14a and the step 14b of various forms may be formed.

The region AR1 may be formed in various shapes if the region AR1 surrounds the through-hole 13.

The method explained as the fifth embodiment is not limited to the circuit boards 10Ea and 10E in which the glass substrate 11 is used in the insulating base materials thereof. The method may also be adopted in formation of circuit boards in which substrates of various fragile materials such as a silicon substrate, a sapphire substrate, and a ceramic substrate are used in a part of or the entire circuit boards.

A sixth embodiment is explained.

An example of an electronic device including the circuit board explained above is explained as a sixth embodiment.

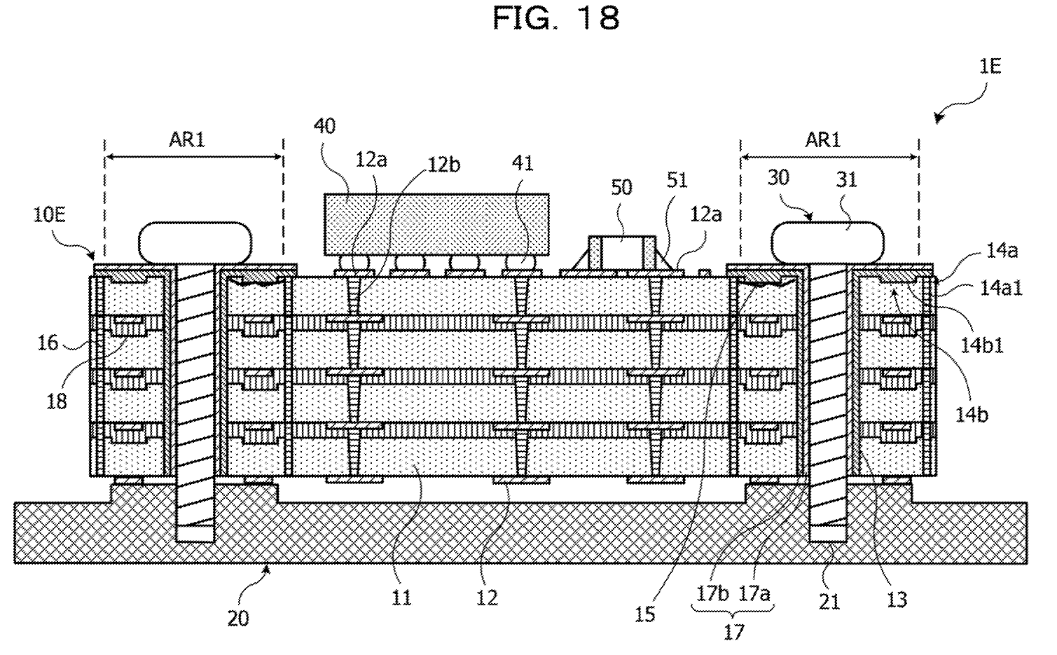

FIG. 18 is a diagram illustrating an example of the electronic device according to the sixth embodiment. In FIG. 18, a main part sectional view of the example of the electronic device is schematically illustrated.

An electronic device 1E illustrated in FIG. 18 includes, as an example, the circuit board 10E formed using the method explained in the fifth embodiment. The circuit board 10E illustrated in FIG. 18 includes terminals 12a (parts of the wire 12) formed on the glass substrate 11 in the top layer and vias 12b formed to pierce through the glass substrates 11 and connect the wires 12 in different layers. Various electronic components are mounted on the circuit board 10E. For example, as illustrated in FIG. 18, a semiconductor chip 40 joined to the terminals 12a of the circuit board 10E using bumps 41 such as solder and a chip component 50 joined to the terminals 12a of the circuit board 10E using joining materials 51 such as solder are mounted on the circuit board 10E.

The circuit board 10E is fixed to the supporting body 20 such as a housing by the screw 30. In the supporting body 20, the fixing section 21, which is a screw hole, to which the screw 30 is tightened, screwed, and fixed is formed in a position corresponding to the through-hole 13 formed in the circuit board 10E. When the circuit board 10E is fixed to the supporting body 20, the circuit board 10E and the supporting body 20 are opposed with the positions of the through-hole 13 and the fixing section 21 thereof aligned. The screw 30 is inserted through the through-hole 13 of the circuit board 10E and tightened to the fixing section 21 of the supporting body 20. According to the tightening of the screw 30, the head 31 of the screw 30 comes into contact with the circuit board 10E. The circuit board 10E is directly fixed to the supporting body 20 by the screw 30. Consequently, the electronic device 1E illustrated in FIG. 18 is obtained.

In the circuit board 10E, the step 14a including the recess is formed at the outer edge of the region AR1 surrounding the through-hole 13 of the group of the glass substrates 11. The step 14b including the recess extending along the direction from the through-hole 13 to the step 14a is formed in the region AR1. With such a configuration, a concentrating region of stress generated in the glass substrate 11 when the screw 30 is tightened and an occurrence region of a crack and a break are adjusted. A crack and a break that occur in the region AR1 illustrated as, for example, the damage 15 in FIG. 18 are stopped from extending to the outside of the region AR1. As a result, the crack and the break are stopped from extending to the wires 12, the terminals 12a, and the vias 12b formed on the glass substrate 11 in the top layer and formed outside the region AR1 of the group of the glass substrates 11 in lower layers of the top layer. Occurrence of a crack and disconnection of the wires 12, the terminals 12a, and the vias 12b and occurrence of a resistance increase and an open failure due to the crack and the break are reduced. Further, an occurrence region of a crack and a break in the region AR1 is adjusted. Occurrence of strength insufficiency and a fixing failure in the other regions is reduced. Consequently, the circuit board 10E having high performance and reliability is realized. Further, the electronic device 1E having high performance and reliability including such a circuit board 10E is realized.

As an example, the electronic device 1E including the circuit board 10E is explained above. However, concerning the circuit boards adopting the various configurations explained in the first to fifth embodiments, electric devices may also be realized by mounting various electronic components on the circuit boards and fixing the circuit boards to the supporting body 20 with the screw 30.

A seventh embodiment is explained.

The circuit boards and the electronic devices explained above may be mounted on various electronic apparatuses. The circuit boards and the electronic devices may be mounted on various electronic apparatuses such as computers (a personal computer, a supercomputer, a server, and the like), a smartphone, a cellular phone, a tablet terminal, a sensor, a camera, an audio apparatus, a measuring apparatus, an inspection apparatus, and a manufacturing apparatus.

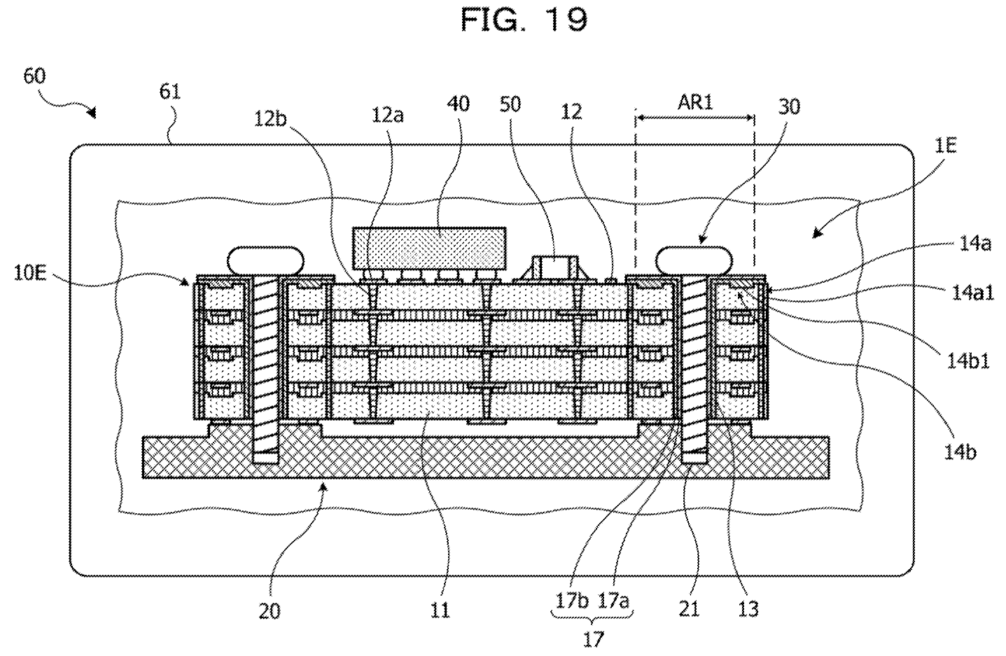

FIG. 19 is an explanatory diagram of an electronic apparatus according to the seventh embodiment. In FIG. 19, the electronic apparatus is schematically illustrated.

As illustrated in FIG. 19, for example, the electronic device 1E (FIG. 18) explained in the sixth embodiment is mounted on the inside of a housing 61 of an electronic apparatus 60. The electronic device 1E is incorporated in the electronic apparatus 60 with the circuit board 10E of the electronic device 1E fixed to, for example, the supporting body 20, which is a part of the housing 61 of the electronic apparatus 60, by the screw 30.

In the electronic device 1E, as explained above, a concentrating region of stress generated in the circuit board 10E when the screw 30 is tightened and an occurrence region of a crack and a break are adjusted. Extension of a crack and a break to the wires 12, the terminals 12a, and the vias 12b formed outside the region AR1 is stopped. A crack and disconnection of the wires 12, the terminals 12a, and the vias 12b are reduced. Further, occurrence of strength insufficiency and a fixing failure of the circuit board 10E is reduced. Consequently, the electronic device 1E with high performance and reliability is realized. Various electronic apparatuses 60 with high performance and reliability mounted with such an electronic device 1E is realized.

As an example, the electronic apparatus 60 mounted with the electronic device 1E explained in the sixth embodiment is explained. However, the circuit boards adopting the various configurations and the electronic devices including the circuit boards explained in the first to sixth embodiments may also be mounted on various electronic apparatuses.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A circuit board comprising:
a first substrate of a fragile material;
a first through-hole formed in the first substrate for allowing a screw for fixing the first substrate to a supporting body to be inserted through the first through-hole;
a first step formed at an outer edge of a first region surrounding the first through-hole in the first substrate; and
a second step formed along a direction from the first through-hole to the first step in the first region of the first substrate.

2. The circuit board according to claim 1, wherein
the first step includes at least one recess or at least one projection, and
the second step includes at least one recess or at least one projection.

3. The circuit board according to claim 1, wherein
the first step includes a plurality of holes or a plurality of protrusions arranged along the outer edge.

4. The circuit board according to claim 1, wherein
the first step includes a groove or a protrusion extended along the outer edge.

5. The circuit board according to claim 1, wherein
the second step includes a plurality of holes or a plurality of protrusions arranged along the direction.

6. The circuit board according to claim 1, wherein
the second step includes a groove or a protrusion extended along the direction.

7. The circuit board according to claim 1, wherein
the first region includes a part where a head of the screw comes into contact with the first substrate when the screw is inserted through the first through-hole.

8. The circuit board according to claim 1, further comprising
a reinforcing layer formed in at least a part from an inner surface of the first through-hole to an upper surface of the first region.

9. The circuit board according to claim 1, further comprising:
a second substrate of a fragile material stacked on the first substrate;
a second through-hole formed in the second substrate and communicating with the first through-hole;
a third step formed in a position corresponding to the outer edge on the second substrate; and
a fourth step formed on the second substrate along a direction from the second through-hole to the third step.

10. A method of manufacturing a circuit board comprising:
forming, in a first substrate of a fragile material, a first through-hole for allowing a screw for fixing the first substrate to a supporting body to be inserted;
forming a first step at an outer edge of a first region surrounding the first through-hole in the first substrate; and
forming, in the first region of the first substrate, a second step along a direction from the first through-hole to the first step.

11. An electronic device comprising:
a supporting body including a screw hole;
a circuit board formed on the supporting body and including a first substrate of a fragile material, a first through-hole formed in the first substrate, a first step formed at an outer edge of a first region surrounding the first through-hole in the first substrate, and a second step formed along a direction from the first through-hole to the first step in the first region of the first substrate; and
a screw inserted through the first through-hole and screwed in the screw hole, the screw fixing the circuit board to the supporting body.

12. The electronic device according to claim 11, wherein
the first substrate has damage terminated in the first step in the first region.
